(19) United States
(12) Patent Application Publication
(10) Pub. No.: US 2025/0048915 A1
(43) Pub. Date: Feb. 6, 2025

(54) LIGHT-EMITTING DEVICE

(71) Applicant: SHARP DISPLAY TECHNOLOGY CORPORATION, Kameyama City, Mie (JP)

(72) Inventor: Haijun LI, Kameyama City, Mie (JP)

(21) Appl. No.: 18/707,925

(22) PCT Filed: Jan. 6, 2022
(86) PCT No.: PCT/JP2022/000213

§ 371 Date: May 7, 2024

(51) Int. Cl. H10K 85/30; H10K 50/844; H10K 50/85; H10K 85/60

(52) U.S. Cl. CPC H10K 85/30; H10K 50/844; H10K 50/85; H10K 85/60

(57) ABSTRACT

A light-emitting device includes: a lower electrode; a functional layer including at least a light-emitting layer; an upper electrode; a first capping layer containing an organic insulating material; and a second capping layer containing a metal complex, all of which are stacked on top of another in a stated order.

### TECHNICAL FIELD

The present disclosure relates to a light-emitting device.

### BACKGROUND ART

A known top-emission light-emitting device includes a capping layer (also referred to as a “cap layer”) provided on an upper electrode for adjusting optical properties of, and protecting, the light-emitting device (e.g., see Patent Document 1).

As such a light-emitting device, Patent Document 1 discloses a display device including: an upper electrode serving as a counter electrode; a first cap layer containing a material having a relatively high refractive index; and a second cap layer containing a material having a relatively low refractive index. The first cap layer and the second cap layer are stacked on top of another in the stated order above the upper electrode. Patent Document 1 discloses, as exemplary materials of the second cap layer, metal fluorides including: lithium fluoride such as alkali metal fluoride salt; and magnesium fluoride and calcium fluoride such as alkali earth metal fluoride salt.

### CITATION LIST

### Patent Literature

[Patent Document 1] Japanese Unexamined Patent Application Publication No. 2019-160417

### SUMMARY

### Technical Problems

However, molecules of metal salt such as the metal fluoride are small and likely to diffuse into a layer adjacent to the second cap layer. Hence, if the metal salt diffuses into the first cap layer, and, for example, a sealing layer is provided on the second cap layer, the metal salt is likely to diffuse into the sealing layer.

Furthermore, if water enters from outside into a capping layer; namely, the second cap layer, containing a metal salt such as alkali metal salt or alkali earth metal salt, metal ions such as alkali metal ions or alkali earth metal ions are generated. When such metal ions are generated in the capping layer, the metal ions might enter the adjacent layer.

Moreover, the capping layer made of such a metal salt exhibits poor uniformity and airtightness, and readily allows water and oxygen to pass therethrough, which increasingly deteriorates optical properties and decreases reliability of the light-emitting device. For example, a light-emitting device including such a capping layer is likely to deteriorate in optical properties (i.e., viewing angle, lifetime, and light extraction efficiency) because of water and oxygen entering from outside. As a result, the light-emitting device could suffer defects such as unevenness, spots, and black dots, and the resulting decrease in reliability.

An aspect of the present disclosure is devised in view of the above problems, and sets out to provide a light-emitting device that excels a known light-emitting device in optical properties and reliability.

### Solution to Problems

In order to solve the above problems, a light-emitting device according to an aspect of the present disclosure includes: a lower electrode; a functional layer including at least a light-emitting layer; an upper electrode; a first capping layer containing an organic insulating material; and a second capping layer containing a metal complex, all of which are stacked on top of another in a stated order.

In order to solve the above problems, a light-emitting device according to an aspect of the present disclosure includes: a lower electrode; a functional layer including at least a light-emitting layer; an upper electrode; a first capping layer containing an organic insulating material; and a second capping layer containing a metal salt, all of which are stacked on top of another in a stated order; and a ligand layer provided adjacent to a lower surface and an upper surface of the second capping layer, and containing ligands that form a complex together with either a metal element, or metal ions, contained in the metal salt.

### Advantageous Effects of Disclosure

An aspect of the present disclosure can provide a light-emitting device that excels a known light-emitting device in optical properties and reliability.

### BRIEF DESCRIPTION OF DRAWINGS

FIG. 1 is a cross-sectional view of an exemplary multilayer structure of a light-emitting device according to a first embodiment.

FIG. 2 is a flowchart showing an exemplary method for producing the light-emitting device according to the first embodiment.

FIG. 3 is a cross-sectional view schematically illustrating a configuration of a film depositing apparatus to be used for forming a second capping layer.

FIG. 4 is a cross-sectional view schematically illustrating a configuration of another film depositing apparatus to be used for forming the second capping layer.

FIG. 5 is a cross-sectional view of an exemplary multilayer structure of a light-emitting device according to a second embodiment.

FIG. 6 is a flowchart showing an exemplary method for producing the light-emitting device according to the second embodiment.

### DESCRIPTION OF EMBODIMENTS

### First Embodiment

### Schematic Configuration of Light-Emitting Device

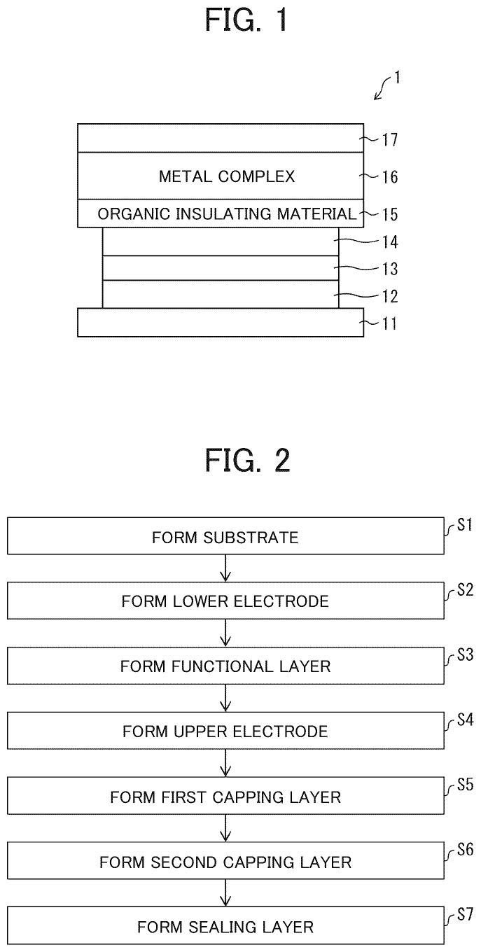

FIG. 1 is a cross-sectional view of an exemplary multilayer structure of a light-emitting device 1 according to this embodiment.

The light-emitting device 1 illustrated in FIG. 1 includes, for example: a substrate 11; a lower electrode 12; a functional layer 13 including at least a light-emitting layer; an upper electrode 14; a first capping layer 15; a second capping layer 16; and a sealing layer 17, all of which are stacked on top of another in the stated order from toward the substrate 11.

Note that, in the present disclosure, the term “below” means that a constituent feature is formed in a previous process before a comparative layer, and the term “above” means that a constituent feature is formed in a successive process after a comparative layer. The term “same layer” means that a constituent feature and the comparative layer are formed in the same process (at the same film forming step). In this embodiment, a direction from the substrate 11 toward the sealing layer 17 is referred to as an upward direction, and a direction opposite the upward direction is referred to as a downward direction. Specifically, in the present disclosure, the term “toward below (or lower)” means that a constituent feature is found closer to the substrate than the comparative layer.

The substrate 11 is a support for forming each of the layers from the lower electrode 12 to the upper electrode 14. Note that the light-emitting device 1 may be a light-emitting element. Alternatively, the light-emitting device 1 may be an electronic appliance such as either a lighting device having at least one light-emitting element or a display device having a plurality of light-emitting elements. Hence, the substrate 11 may be, for example, a glass substrate. Alternatively, the substrate 11 may be a flexible substrate such as a plastic substrate or a plastic film. Furthermore, the substrate 11 may be an array substrate on which a plurality of thin-film transistors are formed. If the light-emitting device 1 is, for example, a light-emitting element that serves as a light source and constitutes an electronic appliance such as a display device, the substrate 11 is used as a substrate of the electronic appliance. Hence, the light-emitting device 1 itself may include the substrate 11. Alternatively, the light-emitting device 1 that omits the substrate 11 may also be referred to as a light-emitting device.

One of the lower electrode 12 or the upper electrode 14 is an anode, and another one is a cathode. The anode receives a voltage and supplies holes to the light-emitting layer. The cathode receives a voltage and supplies electrons to the light-emitting layer. The lower electrode 12 and the upper electrode 14 are connected to a not-shown power supply (e.g., a DC power supply), so that a voltage is applied between the lower electrode 12 and the upper electrode 14. Each of the lower electrode 12 and the upper electrode 14 contains a conductive material, and electrically connects to the functional layer 13.

The light-emitting device 1 according to this embodiment is a top-emission light-emitting device in which light emitted from the light-emitting layer is released from toward the upper electrode 14. For this reason, the upper electrode 14 is a light-transparent electrode and the lower electrode 12 is a reflective electrode.

The light-transparent electrode is formed of a conductive light-transparent material such as, for example, indium tin oxide (ITO), indium zinc oxide (IZO), silver nanowire (AgNW), a thin-film of a magnesium-silver (MgAg) alloy, or a thin-film of silver (Ag).

Whereas, the reflective electrode is formed of a conductive light-reflective material including a metal such as silver (Ag), magnesium (Mg), or aluminum (Al), or including an alloy containing these metals. Note that a layer made of the light-transparent material and a layer made of the light-reflective material may be stacked on top of another to form the reflective electrode.

In this embodiment, the layers between the lower electrode 12 and the upper electrode 14 facing each other are collectively referred to as the functional layer 13.

The functional layer 13 includes at least a light-emitting layer as described above. The functional layer 13 may be either a single layer made of the light-emitting layer alone, or a multilayer including a functional layer other than the light-emitting layer.

If the light-emitting device 1 is either an organic light-emitting diode (an OLED) or an electronic appliance including an OLED as a light-emitting element, the light-emitting layer is formed of a light-emitting material made of an organic material. The organic light-emitting material may be either a phosphorescent light-emitting material or a fluorescent light-emitting material. Furthermore, the light-emitting layer may be of a binary-component system formed of a host material that transports holes and electrons and a light-emitting dopant material that serves as a light-emitting material and emits light. Alternatively, the light-emitting layer may be formed of a light-emitting material alone.

The light-emitting material shall not be limited to a particular material, and may be any given various known light-emitting materials. For example, if the light-emitting device 1 is either a red light-emitting element containing a red organic light-emitting material serving as a light-emitting material or an electronic appliance such as a display device containing the red light-emitting element, examples of the red organic light-emitting material include tris(1-phenylisoquinoline) iridium (III) (Ir(piq)3 for short) and tetraphenyldibenzoperifuranthene (DBP for short). If the light-emitting device 1 is either a green light-emitting element containing a green organic light-emitting material serving as a light-emitting material or an electronic appliance such as a display device containing the green light-emitting element, examples of the green organic light-emitting material include an orthometalated iridium complex (Ir(ppy)3 for short) and 3-(2-benzothiazolyl)-7-(diethylamino) coumarin (coumarin 6 for short). If the light-emitting device 1 is either a blue light-emitting element containing a blue organic light-emitting material serving as a light-emitting material or an electronic appliance such as a display device containing the blue light-emitting element, examples of the blue organic light-emitting material include 4,4′-bis(9-ethyl-3-carbazovinylene)-1,1′-biphenyl (BczVBi for short) and 2,5,8,11-tetra-tert-butylperylene (TBPe for short). Note that the above materials are examples. The light-emitting material shall not be limited to the above materials.

Furthermore, the light-emitting device 1 or a light-emitting element included in the light-emitting device 1 shall not be limited to the OLED, and may be, for example, a quantum-dot light-emitting diode (QLED).

If the light-emitting device 1 or a light-emitting element included in the light-emitting device 1 is, for example, a QLED, the light-emitting layer may contain, as a light-emitting material, quantum dots (hereinafter referred to as “QDs”) in a nano-size depending on a color of the light. The QDs may be known QDs. The QDs are dots made of inorganic nanoparticles each having a maximum width of 100 nm or less. The QDs are also referred to as semiconductor nanoparticles because a typical composition of the QDs is derived from a semiconductor material. Furthermore, the QDs may also be referred to as nanocrystals because a structure of the QDs is a specific crystal structure.

A QD may have any given shape as long as the maximum width of the QD is within the above range. The shape of the QD shall not be limited to a spherical shape (a circular cross-section). For example, the quantum dot may have a polygonal cross-section, a bar-like three dimensional shape, a branch-like three dimensional shape, or a three dimensional shape having asperities on the surface. Alternatively, the quantum dot may have a combination of those shapes.

Each of the QDs may be a core QD. Alternatively, each of the QDs may be either a core-shell QD or a core-multishell QD containing a core and a shell. Furthermore, the QD may be a binary-core QD, a tertiary-core QD, or a quaternary-core QD. Note that the QDs may contain doped nanoparticles, or may have a composition-gradient structure.

The core may be formed of, for example, Si, Ge, CdSe, CdS, CdTe, InP, GaP, InN, ZnSe, ZnS, ZnTe, CdSeTe, GaInP, or ZnSeTe. The shell may be formed of, for example, CdS, ZnS, CdSSe, CdTeSe, CdSTe, ZnSSe, ZnSTe, ZnTeSe, or AIP.

An emission wavelength of the QDs can be changed in various manners depending on, for example, the size and the composition of the particles. The QDs emit visible light. A particle size and a composition of the QDs are appropriately adjusted so that an emission wavelength of the QDs can be controlled from a blue wavelength region to a red wavelength region.

The functional layer 13 may further optionally include such not-shown layers as a hole injection layer, a hole transport layer, an electron blocking layer, a hole blocking layer, an electron transport layer, and an electron injection layer.

The hole injection layer contains a hole transporting material, and functions to increase efficiency in injecting the holes into the hole transport layer. The hole transport layer contains a hole transporting material, and functions to increase efficiency in transporting the holes to the light-emitting layer. The hole injection layer and the hole transport layer may be formed as independent layers, or may be integrated as a hole injection-transport layer. Furthermore, the hole injection layer and the hole transport layer do not have to be provided simultaneously. The hole transport layer may be provided alone.

The electron injection layer contains an electron transporting material, and functions to increase efficiency in injecting the electrons into the electron transport layer. The electron transport layer contains an electron transporting material, and functions to increase efficiency in transporting the electrons to the light-emitting layer. The electron injection layer and the electron transport layer may be formed as independent layers, or may be integrated as an electron injection-transport layer. Furthermore, the electron injection layer and the electron transport layer do not have to be provided simultaneously. The electron transport layer may be provided alone.

The hole blocking layer, which blocks transportation of the holes, is provided between the anode and the light-emitting layer. As a hole blocking material, for example, an organic insulating material can be used. Furthermore, the hole blocking material may also be an electron transporting material. The hole blocking layer can adjust the balance of carriers (i.e., the holes and the electrons) to be supplied to the light-emitting layer.

The electron blocking layer, which blocks transportation of the electrons, is provided between the cathode and the light-emitting layer. As an electron blocking material, for example, an organic insulating material can be used. Furthermore, the electron blocking material may also be a hole transporting material. The electron blocking layer can adjust the balance of carriers (i.e., the holes and the electrons) to be supplied to the light-emitting layer.

These materials of the layers shall not be limited to particular materials, and various known electron transporting materials can be used as a hole transporting material, an electron transporting material, or an organic insulating material.

In this embodiment, as an example, the anode, the hole injection-transport layer, the electron blocking layer, the light-emitting layer, the hole blocking layer, the electron transport-injection layer, the cathode, the first capping layer 15, the second capping layer 16, and the sealing layer 17 are stacked on top of another above the substrate 11 in the stated order. Note that, as described above, the light-emitting device 1 according to this embodiment shall not be limited to the above multilayer structure.

The light-emitting device 1 according to this embodiment may have a known structure in which the lower electrode 12 serves as the anode and the upper electrode 14 serves as the cathode as described above. Alternatively, the light-emitting device 1 may have an inverted structure in which the lower electrode 12 serves as the cathode and the upper electrode 14 serves as the anode. If the light-emitting device 1 has an inverted structure, for example, the cathode, the electron transport-injection layer, the hole blocking layer, the light-emitting layer, the electron blocking layer, the hole injection-transport layer, the anode, the first capping layer 15, the second capping layer 16, and the sealing layer 17 may be stacked on top of another above the substrate 11 in the stated order. Note that, as a matter of course, the functional layer 13 shall not be limited to the hole injection-transport layer, the electron blocking layer, the light-emitting layer, the hole blocking layer, and the electron transport-injection layer. As described above, the layers other than the light-emitting layer are optional and not essential. Furthermore, a thickness of each of the above layers may be appropriately set in accordance with the material of each layer and the kind of a film depositing apparatus for depositing the layer, so that a desired optical path length can be obtained in accordance with a color of the light to be emitted. The thickness shall not be limited to a particular thickness.

Each of the first capping layer 15 and the second capping layer 16 is provided so as to cover the entire surface of the light-emitting region, and functions as an optical adjustment layer that adjusts light emitted from the upper electrode 14 and also as a protective layer that protects the upper electrode 14. The first capping layer 15 and the second capping layer 16 provided above the upper electrode 14 can prevent or keep water and oxygen from entering from above; that is, for example, from the sealing layer 17. Such a feature makes it possible to adjust optical characteristics such as viewing angle, lifetime, and light extraction efficiency.

The first capping layer 15, which contains an organic insulating material, is formed on the upper electrode 14 to cover the upper electrode 14. The second capping layer 16, which contains a metal complex, is formed on, and adjacent to, the first capping layer 15 to cover the first capping layer 15.

The first capping layer 15 and the second capping layer 16 are made of a material that does not decrease the luminance or deteriorate the characteristics of light to be emitted from the light-emitting layer as much as possible.

The first capping layer 15 is desirably transparent to visible light, and higher in refractive index than the second capping layer 16. Examples of the organic insulating material used for the first capping layer 15 include light-transparent organic insulating materials such as an acrylic-based resin and a siloxane-based resin.

Whereas, the second capping layer 16 is desirably transparent to visible light, and lower in refractive index than the first capping layer 15.

As can be seen, when each of the first capping layer 15 and the second capping layer 16 is formed of a light-transparent material, the light-emitting device 1 can include the first capping layer 15 and the second capping layer 16 each of which is transparent to light.

The second capping layer 16 contains a metal complex. The metal complex preferably contains at least one complex selected from an alkali metal complex having an alkali metal as a central metal (a Lewis acid) and an alkali earth metal complex having an alkali earth metal as a central metal (a Lewis acid).

The metal complex can be obtained when a metal salt and ligands containing a Lewis base react together. The metal salt preferably contains at least one metal salt selected from an alkali metal salt and an alkali earth metal salt. The alkali metal complex can be obtained when an alkali metal salt and ligands containing a Lewis base react together. Likewise, the alkali earth metal complex can be obtained when an alkali metal earth salt and ligands containing a Lewis base react together.

Note that, in the present disclosure, the ligands are molecules or ions capable of forming a complex together with either a metal element, or metal ions, contained in the metal salt. The ligands may form a complex together with either a metal element, or metal ions, contained in the metal salt. The ligands may coordinate with the metal element or the metal ions. Alternatively, the ligands do not have to coordinate with the metal element or the metal ions. In the present disclosure, the term “ligands” collectively refers not only to molecules or ions that coordinate with the central metal but also to molecules or ions that can coordinate but do not coordinate. Furthermore, in the present disclosure, molecules or ions capable of donating an unshared electron pair are referred to as a Lewis base, regardless of whether the unshared electron pair is shared with the central metal (i.e., whether the molecules coordinate or form a complex).

Examples of the alkali metal include Li, Na, K, Rb, and Cs. Examples of the alkali earth metal include Mg, Ca, Sr, and Ba.

Furthermore, the at least one complex selected from the alkali metal complex and the alkali earth metal complex is preferably at least one halide complex selected from an alkali metal halide complex and an alkali earth metal halide complex.

In this case, an alkali metal halide (an alkali metal halide salt) is used as the alkali metal salt. Moreover, an alkali earth metal halide (an alkali earth metal halide salt) is used as the alkali earth metal salt.

Examples of the alkali metal halide include LiF, LiCl, NaF, and KF. Examples of the alkali earth metal halide include MgF₂, MgCl₂, and CaF₂.

If the alkali metal complex is an alkali metal halide complex, the alkali metal halide complex contains a halogen such as F or Cl serving as counterions. Likewise, if the alkali earth metal complex is an alkali earth metal halide complex, the alkali earth metal halide complex contains a halogen such as F or Cl serving as counterions.

The Lewis base shall not be limited to a particular Lewis base as long as the Lewis base has at least one unshared electron pair, and can donate electrons to the metal salt to form a metal complex. Note that, as described above, the second capping layer 16 is preferably transparent to visible light. Hence, the Lewis base is preferably a light-transparent Lewis base.

Furthermore, the Lewis base contains at least one atom selected from the group consisting of a nitrogen atom, an oxygen atom, and a phosphorus atom.

Hence, the ligands contained in the metal complex preferably contain a Lewis base having at least one atom serving as a coordination atom and selected from the group consisting of a nitrogen atom, an oxygen atom, and a phosphorus atom. Moreover, the ligands contained in the second capping layer 16 preferably contain a Lewis base containing at least one atom selected from the group consisting of a nitrogen atom, an oxygen atom, and a phosphorus atom.

The nitrogen atom, the oxygen atom, and the phosphorus atom are negatively charged. Thanks to such a feature, positively charged metal ions are stably captured so that the complex is readily formed. Simultaneously, the feature makes it possible to prevent deterioration of the optical characteristics more reliably.

Examples of the ligands contained in the metal complex include a Lewis base containing at least one structural unit selected from the group consisting of structural units represented by Formulae (1) to (4) below.

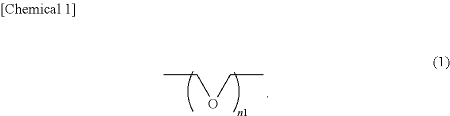

Wherein, in Formula (1), n1 represents an integer of 1 or more.

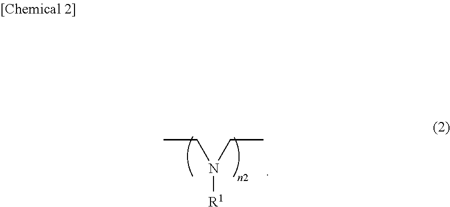

Wherein, in Formula (2), R¹ represents either a hydrogen atom or a substituted or unsubstituted, and branched-chain, linear, or cyclic hydrocarbon group, and n2 represents an integer of 1 or more.

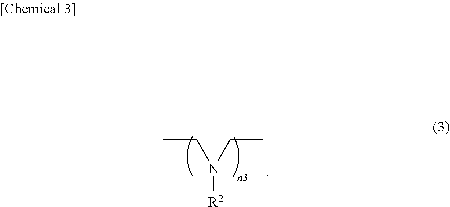

Wherein, in Formula (3), R² represents either a hydrogen atom or a substituted or unsubstituted, and branched-chain, linear, or cyclic hydrocarbon group, and n3 represents an integer of 1 or more.

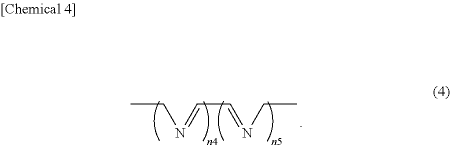

Wherein, in Formula (4), each of n4 and n5 independently represents an integer of 0 or 1 or more, and n4+n5 represents an integer of 1 or more.

In Formulae (1) to (4), n1, n2 and n3 are, for example, monodentate ligands if “1” (e.g., n1=1, n2=1, n3=1), bidentate ligands if “2”, tridentate ligands if “3”, tetradentate ligands if “4”, and the same applies hereinafter.

In Formula (4), if n4+n5=1, the ligands are monodentate ligands, if n4+n5=2, the ligands are bidentate ligands, if n4+n5=3, the ligands are tridentate ligands, if n4+n5=4, the ligands are tetradentate ligands, and the same applies hereinafter.

Note that if each of R¹ and R² is a substituted or unsubstituted, and branched-chain, linear, or cyclic hydrocarbon group, the number of carbon atoms in the hydrocarbon group shall not be limited to a particular number. However, if the number of carbon atoms is excessively large, the molecular weight increases excessively, and the compound used as the ligands might become unstable. Simultaneously, the sublimation temperature rises, and the power to be consumed for the sublimation increases. Hence, the number of carbon atoms is preferably an integer of 1 or more and 18 or less.

As can be seen, the ligands (the Lewis base) may be monodentate ligands, or bidentate or higher multidentate ligands. Note that, compared with multidentate ligand, monodentate ligand have weaker binding strength with metal. Hence, the ligands contained in the metal complex preferably contain multidentate ligands.

Thus, in Formulae (1) to (3), each of n1, n2 and n3 is preferably independent and an integer of 2 or more. Upper limit values of n1, n2, and n3 shall not be limited to particular values. However, if the number of repeating units represented by n1, n2 and n3 is excessively large, the molecular weight might become excessively large, such that the compound used as the ligands might become unstable. Hence, each of n1, n2, and n3 is preferably an integer of 9 or less. Furthermore, in Formula (4), each of n4 and n5 is preferably independent and an integer of 0 or 1 or more, and n4+n5 is preferably an integer of 2 or more. For the same reason as for n1 to n3, each of n4 and n5 is preferably independent and an integer of 9 or less, and n4+n5 is preferably an integer of 9 or less.

Moreover, the ligands more preferably include tridentate or higher multidentate ligands having a cyclic structure. Hence, as to the ligands (a Lewis base) containing at least one structural unit represented by Formulae (1) to (3), each of n1, n2 and n3 is preferably independent and an integer of 3 or more and 9 or less, and the ligands preferably have a cyclic structure. Furthermore, as to the ligands (a Lewis base) containing a structural unit represented by Formula (4), each of n4 and n5 is preferably independent and an integer of 0 or 1 or more and 9 or less, and the ligands preferably have a cyclic structure.

Examples of the cyclic multidentate ligands having a cyclic structure include crown ethers having a structural unit represented by Formula (1), such as 12-crown-4 represented by Formula (5), 15-crown-5 represented by Formula (6), and 18-crown-6 represented by Formula (7).

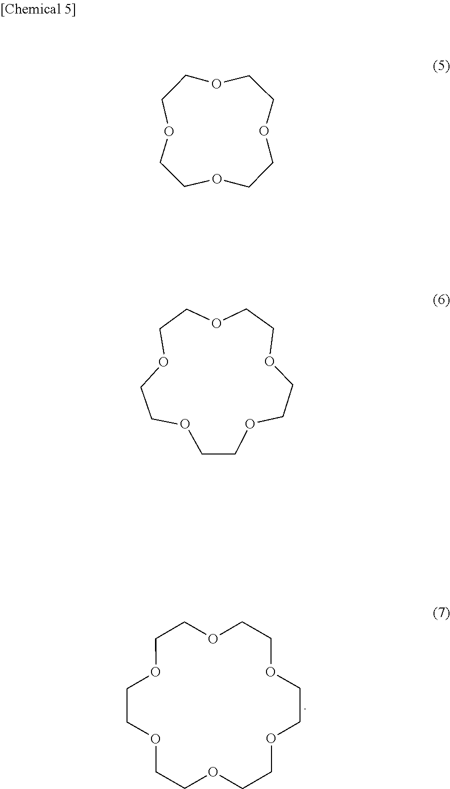

These crown ethers are Lewis bases having Lewis basicity, and containing a plurality of oxygen atoms as elements serving as electron donors (Lewis basic elements). These oxygen atoms are coordination atoms. As described above, the ligands contained in the metal complex contain negatively charged oxygen atoms. Thanks to such a feature, positively charged metal ions are stably captured so that the complex is readily formed. Simultaneously, the feature makes it possible to prevent deterioration of the optical characteristics more reliably.

Furthermore, the cyclic multidentate ligands having a structural unit represented by Formula (1) may be a derivative of the crown ether represented by either Formular (8) or Formular (9).

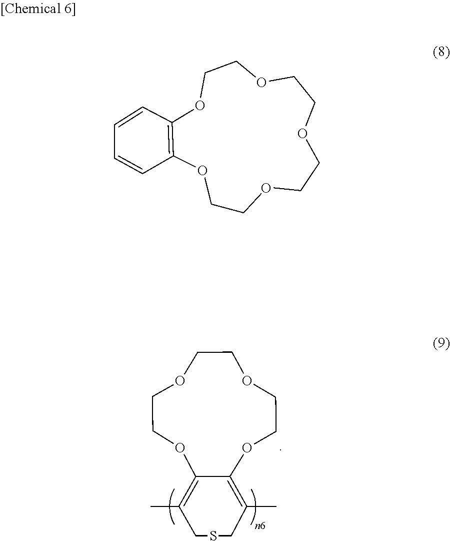

Wherein, in Formula (9), n6 represents an integer of, for example, 1 or more.

The ligands represented by Formula (8) form the same kind of cycle as the ligands (15-crown-5) represented by Formula (6). Hence, the ligands represented by Formula (8) capture Na ions well to form a complex. Furthermore, the ligands represented by Formula (9) form the same kind of cycle as the ligands (12-crown-4) represented by Formula (6). Hence, the ligands represented by Formula (9) capture Li ions well to form a complex.

Moreover, the ligands represented by Formula (8) are greater in molecular weight than the ligands represented by Formula (6), and the ligands represented by Formula (9) are greater in molecular weight than the ligands represented by Formula (5). As can be seen, when the ligands form a derivative, the molecular weight increases such that the captured metal ions are less likely to move. Such a feature makes it possible to prevent deterioration of optical properties more reliably.

In addition, the crown ethers may have a structure in which at least one of oxygen atoms is substituted with, for example, a nitrogen atom or a phosphorus atom as illustrated in, for example, Formulae (10) to (13) below, and a side chain such as an alkyl group is added to the nitrogen atom.

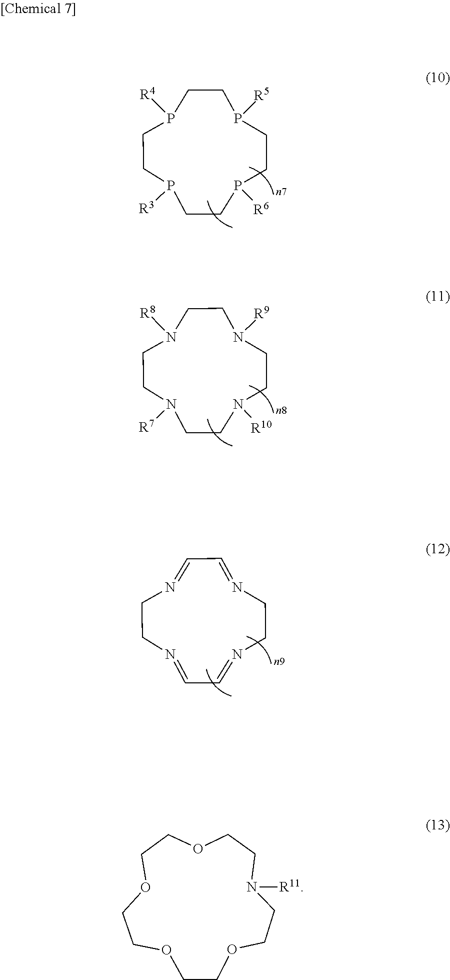

Note that, wherein, each of n7 in Formula (10), n8 in Formula (11), and n9 in Formula (12) is preferably independent and an integer of, for example, 1 or more and 6 or less. Furthermore, each of R³ to R⁶ in Formula (10), R⁷ to R¹⁰ in Formula (11), and R¹¹ in Formula (13) represents either a hydrogen atom or a substituted or unsubstituted, and branched-chain, linear, or cyclic hydrocarbon group. Note that if any one or more of R³ to R¹¹ are substituted or unsubstituted, and branched-chain, linear, or cyclic hydrocarbon groups, the number of carbon atoms in the hydrocarbon groups shall not be limited to a particular number. However, if the number of carbon atoms is excessively large, the molecular weight increases excessively, and the compound used as the ligands might become unstable. Simultaneously, the sublimation temperature rises, and the power to be consumed for the sublimation increases. Hence, the number of carbon atoms is preferably an integer of 1 or more and 18 or less.

The ligands represented by Formulae (10) to (13) are Lewis bases containing, for example, nitrogen atoms, phosphorus atoms, or oxygen atoms serving as a Lewis basic element, and having the Lewis basic element as coordination atoms. The ligands represented by Formula (10) have a structural unit represented by, for example, Formula (2). Examples of the ligands represented by Formula (10) include cyclen in which n7=1 and R³ to R⁶ are hydrogen atoms. The ligands represented by Formula (11) have a structural unit represented by, for example, Formula (3). The ligands represented by Formula (12) have a structural unit represented by, for example, Formula (4). The ligands represented by Formula (13) have structural units represented by, for example, Formulae (1) and (2). Hence, the ligands contained in the metal complex may contain a Lewis base having nitrogen atoms or phosphorus atoms serving as coordination atoms, and may contain a Lewis base having two or more atoms serving as coordination atoms and selected from the group consisting of a nitrogen atom, an oxygen atom, and a phosphorus atom.

As can be seen, the ligands are bound more suitably to positively charged metal ions (a Lewis acid) (i.e., the metal ions are captured in greater amount). Thanks to such a feature, the complex is readily formed. Simultaneously, the feature makes it possible to prevent deterioration of the optical characteristics more reliably.

As described above, if the ligands contain, for example, tridentate or higher multidentate ligands having a cyclic structure, the cycle to be selected corresponds to the size of the metal ions to be captured (i.e., to be bound). Such a feature makes it possible to selectively capture the metal ions so that the ligands can capture the metal ions in a more suitable manner.

For example, 15-crown-5 represented by Formula (6) exhibits high selectivity for Na ions, and successfully captures Na ions in a more suitable manner to form a complex.

Furthermore, 12-crown-4 represented by Formula (5) forms a cycle smaller than a cycle of 14-crown-5 represented by Formula (6). Hence, 12-crown-4 exhibits high selectivity for Li ions smaller than Na ions, and successfully captures Li ions in a more suitable manner to form a complex.

Moreover, 18-crown-6 represented by Formula (6) forms a cycle larger than a cycle of 15-crown-5 represented by Formula (6). Hence, 18-crown-6 exhibits high selectivity for K ions larger than Na ions, and successfully captures K ions in a more suitable manner to form a complex.

Formula (14) shows a reaction of 18-crown-6 and KF; namely, a kind of alkali metal halide salt.

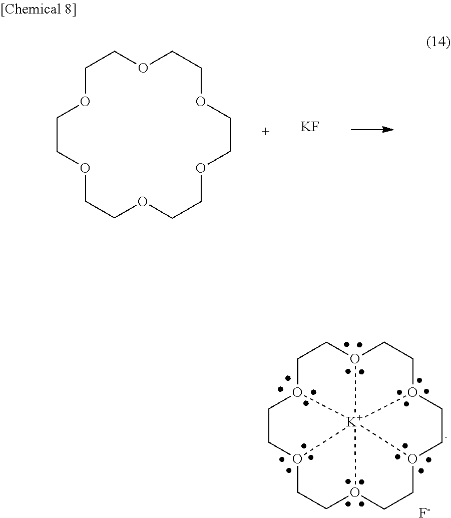

As can be seen, 18-crown-6 reacts with, for example, KF to form KF 18-crown-6 serving as a metal complex. Thus, 18-crown-6 can capture K ions in a more suitable manner to form a complex. If the second capping layer 16 contains KF 18-crown-6 serving as a metal complex, the second capping layer 16 contains 18-crown-6 as ligands and fluoride ions as counterions.

Furthermore, Formula (15) shows a reaction of 12-crown-4 and LiF; namely, a kind of alkali metal halide salt.

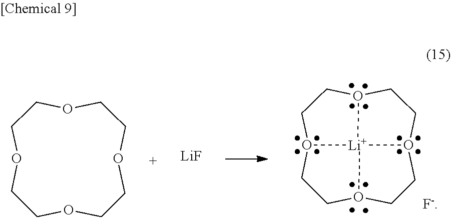

As can be seen, 12-crown-4 reacts with, for example, LiF to form LiF 12-crown-4 serving as a metal complex. Thus, 12-crown-4 can capture Li ions in a more suitable manner to form a complex. If the second capping layer 16 contains LiF 12-crown-4 serving as a metal complex, the second capping layer 16 contains 12-crown-4 serving as ligands and fluoride ions serving as counterions.

Note that, although not shown, 15-crown-5 can react with a Na halide such as, for example, NaF, and capture Na ions in a more suitable manner to form a complex.

The metal complex contained in the second capping layer 16 may be either an alkali metal halide complex described above, or an alkali earth metal halide complex.

Note that the metal complex contained in the second capping layer 16 shall not be limited to either an alkali metal halide complex, or an alkali earth metal halide complex. Examples of a metal complex containing 12-crown-4 as ligands include LiCN·12-crown-4 represented by Formula (16). Examples of a metal complex containing 15-crown-5 as ligands include NaOH 15-crown-5 represented by Formula (17). Examples of a metal complex containing 18-crown-6 as ligands include KMnO₄·18-crown-6 represented by Formula (18).

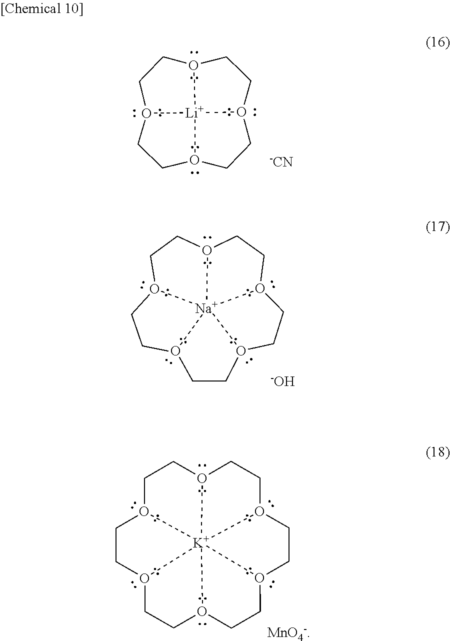

As can be seen, the metal complex contained in the second capping layer 16 may have anions, serving as counterions, other than halogen ions. In other words, the second capping layer 16 may contain anions other than halogen ions.

Furthermore, as described above, ligands (a Lewis base) forming the same kind of cycle are bound to the same kind of Lewis acid. As described above, for example, the ligands represented by Formula (8) form the same kind of cycle as a cycle of the ligands (15-crown-5) represented by Formula (6), and capture Na ions in a suitable manner to form a complex.

The ligands represented by Formula (8) capture Na ions, to form, for example, a complex (complex ions) represented by Formulae (19) to (21).

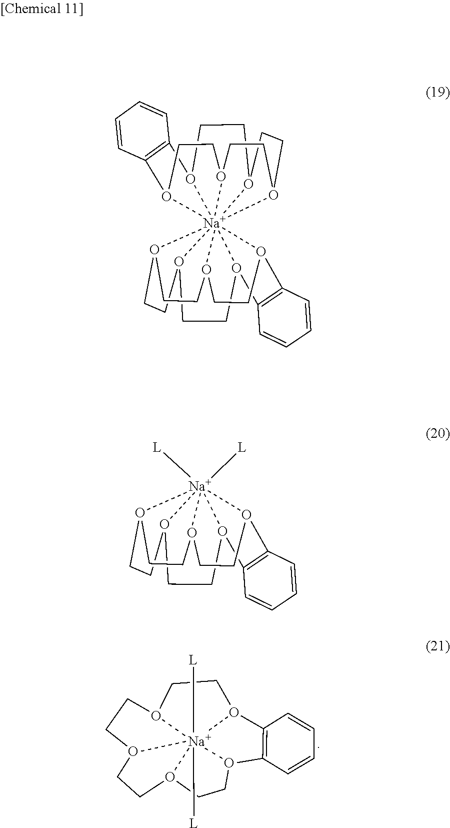

Note that Formula (19) omits counterions. In Formulae (20) and (21), L represents counterions.

Note that, as described above, if the ligands contain, for example, tridentate or higher multidentate ligands having a cyclic structure, the cycle to be selected corresponds to the size of the metal ions to be captured (i.e., to be bound). Such a feature makes it possible to selectively capture the metal ions. As a result, for example, the number of repeating units represented by n7 to n9 in Formulae (10) to (12) is adjusted and the size of the cycles is changed. Such a feature makes it possible to form a metal complex containing desired metal ions as a central metal. As a matter of course, the same applies to ligands other than the ligands represented by Formulae (10) to (12).

Note that, as an example, Formulae (5) to (13) show ligands having a structural unit represented by any one of Formulae (1) to (4). However, the ligands containing at least one structural unit selected from the group consisting of the structural units represented by Formulae (1) to (4) shall not be limited to cyclic ligands. The ligands may be chain ligands.

Examples of the chain ligands having a structural unit represented by Formula (1) include triglyme represented by Formula (22) and tetraglyme represented by Formula (23).

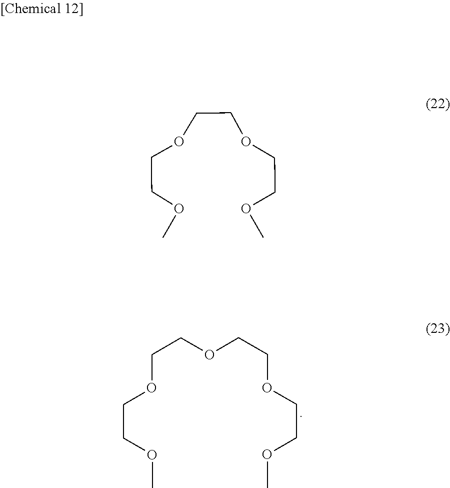

Formula (24) represents an example of a metal complex containing: Li ions as a central metal (a Lewis acid); and triglyme represented by Formula (22) as ligands (a Lewis base). Furthermore, Formula (25) represents an example of a metal complex containing: Li ions as a central metal (a Lewis acid); and tetraglyme represented by Formula (23) as ligands (a Lewis base).

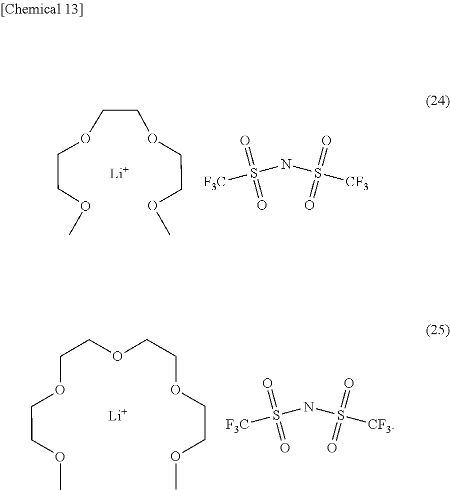

Moreover, examples of the chain ligands having a structural unit represented by Formula (2) include a Lewis base represented by Formula (26). Examples of the chain ligands having a structural unit represented by Formula (3) include a Lewis base represented by Formula (27). Examples of the chain ligands having a structural unit represented by Formula (4) include a Lewis base represented by Formula (28).

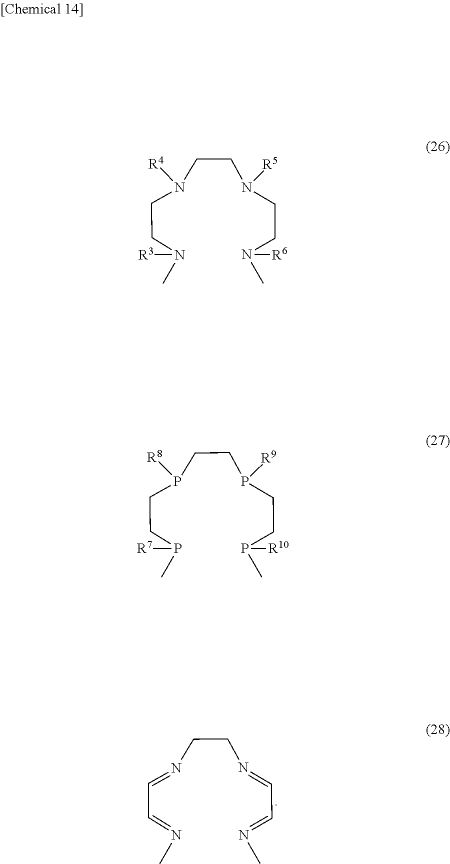

Note that each of R³ to R⁶ in Formula (26) and R⁷ to R¹⁰ in Formula (27) represents either a hydrogen atom or a substituted or unsubstituted, and branched-chain, linear, or cyclic hydrocarbon group. The ligands represented by Formula (26) are, for example, the ligands in Formula (10) with n7=1 and the ring opening. The ligands represented by Formula (27) are, for example, the ligands in Formula (11) with n8=1 and the ring opening. The ligands represented by Formula (28) are, for example, the ligands in Formula (12) with n9=1 and the ring opening.

Hence, the chain ligands having the structural unit represented by Formula (2) may be, for example, the ligands represented by Formula (10) while n7 is any one of 2 to 6 and the ring is open. Likewise, the chain ligands having the structural unit represented by Formula (2) may be, for example, the ligands represented by Formula (11) while n8 is any one of 2 to 6 and the ring is open. The chain ligands having the structural unit represented by Formula (4) may be, for example, the ligands represented by Formula (12) while n9 is any one of 2 to 6 and the ring is open.

Formula (29) represents a metal complex containing the Lewis base represented by Formula (26) as ligands. Formula (30) represents a metal complex containing the Lewis base represented by Formula (27) as ligands. Formula (31) represents a metal complex containing the Lewis base represented by Formula (28) as ligands.

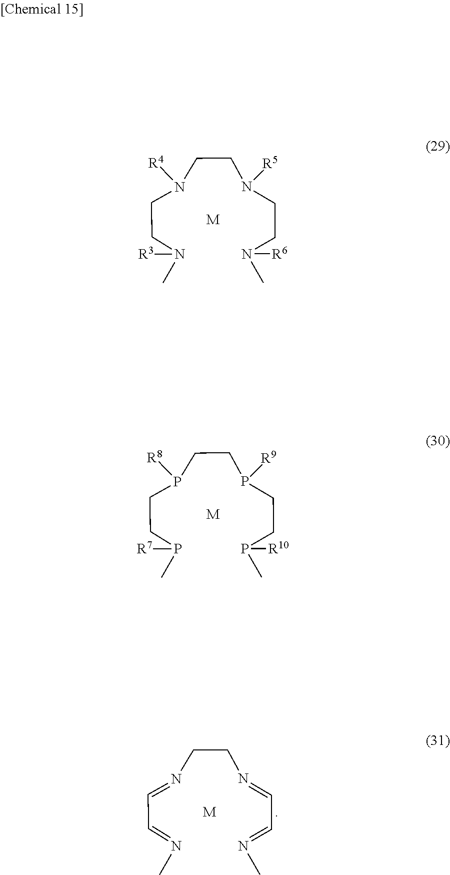

Wherein, in Formulae (29) to (31), M represents a central metal (a Lewis acid). M may be either an alkali metal or an alkali earth metal. Formulae (29) to (31) omit valence and counterions.

As can be seen, the ligands contained in the second capping layer 16 may be chain ligands. Note that the ligands contained in the second capping layer 16 shall not be limited to the above ligands described as examples. The ligands may be, for example, monodentate ligands having at least one bond selected from the group consisting of C═C, C═O, C═C, C═N, NR₃, and PR₃.

Furthermore, the ligands may be bidentate ligands having at least one structure selected from the group consisting of Formulae (32) to (34).

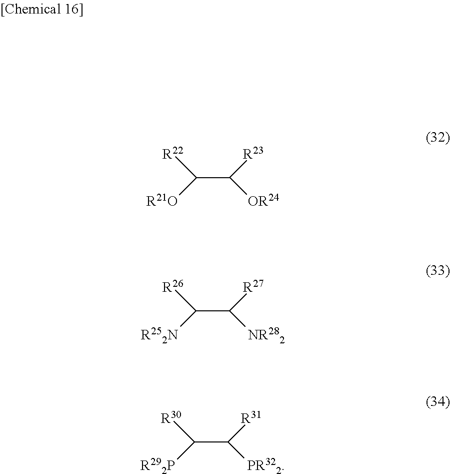

Note that, in Formulae (32) to (34), each of R²¹ to R³² represents a hydrogen atom or a substituted or unsubstituted, and branched-chain, linear, or cyclic hydrocarbon group. If any one or more of R²¹ and R³² are substituted or unsubstituted, and branched-chain, linear, or cyclic hydrocarbon groups, the number of carbon atoms in the hydrocarbon groups shall not be limited to a particular number. However, if the number of carbon atoms is excessively large, the molecular weight increases excessively, and the compound used as the ligands might become unstable. Simultaneously, the sublimation temperature rises, and the power to be consumed for the sublimation increases. Hence, the number of carbon atoms is preferably an integer of 1 or more and 18 or less.

The sealing layer 17 is a layer that prevents foreign substances such as water and oxygen from penetrating into a layer (particularly, into the light-emitting layer) below the sealing layer 17. In this embodiment, as illustrated in FIG. 1, the sealing layer 17 is provided on the second capping layer 16. As an example, the sealing layer 17 includes: a first inorganic sealing film covering the second capping layer 16, an organic buffer film above the first inorganic sealing film, and a second inorganic sealing film above the organic buffer film.

Each of the first inorganic sealing film and the second inorganic sealing film is a light-transparent inorganic sealing film. The light-transparent inorganic sealing film can be formed of, for example, an inorganic insulating film such as a silicon oxide film or a silicon nitride film formed by chemical vapor deposition (CVD). The organic buffer film is a light-transparent organic insulating film exhibiting a planarizing effect. The organic buffer film can be made of an applicable organic material such as acrylic.

Furthermore, the sealing layer 17 may be laminated with a not-shown appropriately-selected functional film formed by application. The functional film has at least one of, for example, an adaptive optics correction function, a touch sensor function, and a protection function.

Note that a thickness of each of the layers in the light-emitting device 1 may be appropriately set in accordance with the material of each layer and the kind of a film depositing apparatus for depositing the layer, so that a desired optical path length can be obtained in accordance with a color of the light to be emitted. The thickness shall not be limited to a particular thickness. The thickness of each layer in the light-emitting device 1 can be set in the same manner as, for example, a known light-emitting device. Hence, the thicknesses of the first capping layer 15 and the thickness of the second capping layer 16 shall not be limited to particular thicknesses, and may be appropriately set in accordance with optical properties of the light-emitting device 1 and the result of a reliability test. Note that, if each layer is excessively thick, the light-emitting device 1 as a whole becomes thick. Accordingly, the light-emitting device 1 becomes large in size. Hence, the first capping layer 15 has a thickness within a range of preferably, for example, more than zero nanometer to several hundred nanometers. As an example, the first capping layer 15 has a thickness of more than 0 nm and 200 nm or less. Furthermore, because of the same reason, the second capping layer 16 has a thickness within a range of preferably, for example, more than zero nanometer to several hundred nanometers. As an example, the second capping layer 16 has a thickness of more than 0 nm and 100 nm or less.

### Advantageous Effects

Described next will be advantageous effects of the second capping layer 16.

A known second capping layer contains metal salts including an alkali metal haloid salt such as lithium fluoride, and an alkali earth metal haloid salt such as magnesium fluoride. Molecules of these metal salts are small and likely to diffuse into a layer adjacent to the second capping layer. Furthermore, if water enters from outside into such a second capping layer, metal ions such as alkali metal ions or alkali earth metal ions are generated. These metal ions might enter an adjacent layer. Moreover, the second capping layer made of such metal salts exhibits poor uniformity and airtightness, and readily allows water and oxygen to pass therethrough, which increasingly deteriorates optical properties and decreases reliability of the light-emitting device.

In contrast, in this embodiment, a Lewis base serving as ligands are introduced into a metal salt such as an alkali earth metal haloid salt or an alkali earth metal haloid salt, in order to form a stable metal complex.

Metal complexes including alkali metal complexes such as an alkali metal haloid complex and alkali earth metal complexes such as an alkali earth metal haloid complex are larger than metal salts including an alkali metal haloid salt and an alkali earth metal haloid salt. Hence, these metal complexes are less likely to diffuse into the first capping layer 15, or the sealing layer 17, adjacent to the second capping layer 16, and have no influence on efficiency in releasing light from the light-emitting device 1.

Furthermore, as to the light-emitting device 1 according to this embodiment, metal salts such as an alkali metal haloid salt and an alkali earth metal haloid salt form a complex, and the gaps between the molecules of these metal salts are filled with ligands. Hence, even if water enters from outside into the second capping layer 16, and metal ions such as alkali metal ions or alkali earth metal ions are generated, these metal ions are trapped by the ligands. Such a feature successfully prevents these metal ions as movable ions from diffusing into the first capping layer 15, or the sealing layer 17, adjacent to the second capping layer 16, and keeps the light-emitting device 1 from deteriorating in optical properties. Moreover, as described above, the gaps between the molecules of the metal salts are filled with the ligands. Thus, the second capping layer 16 according to the present embodiment has higher uniformity and airtightness than the known second capping layer. Hence, this embodiment can provide the light-emitting device 1 that excels a known light-emitting device in optical properties including efficiency in releasing light. Furthermore, this embodiment makes it possible to reduce deterioration of the optical properties over time, and to provide the light-emitting device 1 with longer lifetime and higher reliability than those of a known light-emitting device.

### Method for Producing Light-Emitting Device 1

Described next will be a method for producing the light-emitting device 1 according to this embodiment.

FIG. 2 is a flowchart showing an exemplary method for producing the light-emitting device 1 according to this embodiment.

As shown in FIG. 2, in this embodiment, first, the substrate 11 is formed (Step S1). If the light-emitting device 1 is, for example, a display device, forming the substrate 11 may involve forming TFTs on a support substrate so that the TFTs are positioned in accordance with the subpixels of the display device.

Next, the lower electrode 12 is formed (Step S2). The lower electrode 12 is formed (i.e., deposited) by, for example, evaporation or sputtering. If the light-emitting device 1 is, for example, a display device, the lower electrode 12 is formed into an island-shaped pattern for each of the pixels. Note that, in forming the lower electrode 12, for example, a conductive material may be monolithically deposited over the entire pixel region (i.e., the display region), and, after that, the conductive material may be patterned by, for example, photolithography for each of pixels P to form the lower electrode 12.

Next, the functional layer 13 is formed (Step S3). Note that, after Step S2 and before Step S3, an edge cover forming step may be carried out as necessary to form an edge cover covering an edge of the lower electrode 12. The edge cover is made of, for example, a photosensitive resin additionally containing a light absorber. The photosensitive resin is applied to the substrate 11 and the lower electrode 12, and, after that, patterned by photolithography to be shaped into a desired shape.

As described above, in this embodiment, as an example, the anode, the hole injection-transport layer, the electron blocking layer, the light-emitting layer, the hole blocking layer, the electron transport-injection layer, the cathode, the first capping layer 15, the second capping layer 16, and the sealing layer 17 are stacked on top of another above the substrate 11 in the stated order. Hence, in this case, Step S2 involves forming an anode serving as the lower electrode 12. Furthermore, Step S3 involves forming the functional layer 13 including, for example: the hole injection-transport layer; the electron blocking layer; the light-emitting layer; the hole blocking layer; and the electron transport-injection layer, all of which are formed in the stated order from below. Hence, in such a case, Step S3 may include: a hole injection-transport layer forming step; an electron blocking layer forming step; a light-emitting layer forming step; a hole blocking layer forming step; and an electron transport-injection layer forming step, all of which are included in the stated order. Note that the above steps in Step S3 are carried out in the above order if the lower electrode 12 is, for example, an anode. As described above, the order of the above steps is reversed if the lower electrode 12 is a cathode.

If the light-emitting layer contains an organic light-emitting material, the light-emitting layer may be formed by, for example, vacuum evaporation and inkjet printing. If the light-emitting layer contains quantum dots, the quantum dots are dispersed into a solvent to prepare a quantum-dot-dispersed solution. The quantum-dot-dispersed solution is applied to form a film, and then, the film is dried to form the light-emitting layer. The quantum-dot-dispersed solution is applied by, for example, spin coating and inkjet printing.

If the light-emitting device 1 is, for example, a display device, the light-emitting layer is formed into an island shape for each of the pixels. A red pixel includes a red light-emitting layer containing a red light-emitting material. A green pixel includes a green light-emitting layer containing a green light-emitting material. A blue pixel includes a blue light-emitting layer containing a blue light-emitting material.

If the light-emitting layer contains an organic light-emitting material, the light-emitting material is separately applied, using a fine metal mask (an FMM) having openings for the respective pixels. If the light-emitting layer contains quantum dots, for example, a resist is used to form a template to be provided on the underlayer and having openings for pixels forming the light-emitting layer. The quantum-dot-dispersed solution is applied monolithically to the template, and dried. After that, the template is removed with a resist solvent, and lifted off. The steps from forming the template to removing the template are repeated (e.g., three times), depending on how many colors light to be emitted has. Hence, the light-emitting layers can be formed for the respective colors.

If each of the hole injection-transport layer, the electron blocking layer, the hole blocking layer, and the electron transport-injection layer is made of an organic material, the layer is formed preferably by, for example, vacuum evaporation, spin coating, or inkjet printing. Whereas, if each of the hole injection-transport layer, the electron blocking layer, the hole blocking layer, and the electron transport-injection layer is made of an inorganic material, the layer is preferably formed by, for example, sputtering, the PVD such as vacuum evaporation, spin coating, or inkjet printing.

After the functional layer 13 is formed, the upper electrode 14 is formed (Step S4). The upper electrode 14 is formed (i.e., deposited) by, for example, evaporation or sputtering. If the light-emitting device 1 is, for example, a display device, the upper electrode 14 is monolithically formed as a common layer in common with all the pixels.

Next, the first capping layer 15 is formed (Step S5). The first capping layer 15 can be formed of an organic insulating material applied by, for example, vacuum evaporation, spin coating, or inkjet printing.

Next, the second capping layer 16 is formed (Step S6). Note that a method for forming the second capping layer 16 will be described later.

Next, the sealing layer 17 is formed (Step S7). As described above, the inorganic sealing film is formed by the CVD. The organic buffer film is formed by, for example, inkjet printing. Note that, here, a not-shown bank may be provided outside the light-emitting region to stop droplets. This is how the light-emitting device 1 illustrated in FIG. 1 is produced. If the light-emitting device 1 has a functional film provided on the sealing layer 17, the functional film is formed after Step S7 is carried out.

### Method for Forming Second Capping Layer 16

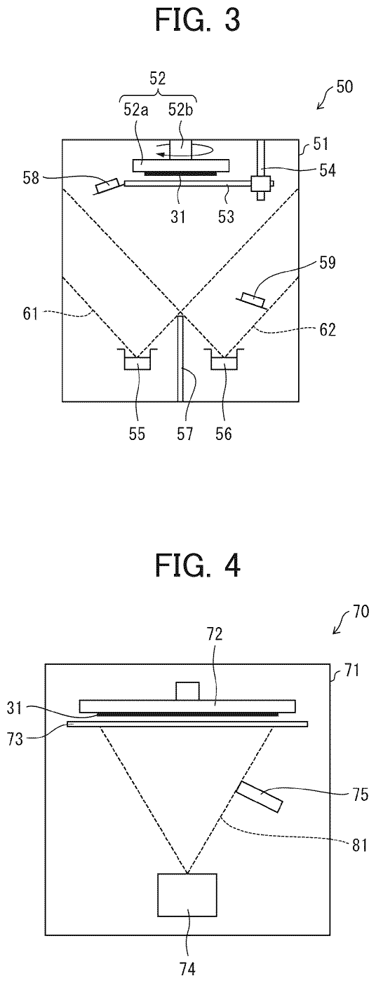

FIG. 3 is a cross-sectional view schematically illustrating a configuration of a film depositing apparatus 50 to be used for forming the second capping layer 16.

The film depositing apparatus 50 includes: a vacuum chamber 51; a substrate supporting unit 52; a shutter 53; a shutter supporting unit 54; a first evaporation-particle ejecting unit 55; a second evaporation-particle ejecting unit 56; a cutting plate 57; a first coating thickness gauge 58; and a second coating thickness gauge 59.

The vacuum chamber 51, which is a film depositing chamber, is provided with a not-shown vacuum pump to exhaust air inside the vacuum chamber 51 through a not-shown exhaust port provided to the vacuum chamber 51, in order to maintain a vacuum inside the vacuum chamber 51.

In the vacuum chamber 51, the substrate supporting unit 52 is disposed across the shutter 53 from the first evaporation-particle ejecting unit 55 and the second evaporation-particle ejecting unit 56 both serving as evaporation sources. In the example illustrated in FIG. 3, the substrate supporting unit 52 and the shutter 53 are provided at the top inside the vacuum chamber 51, and the first evaporation-particle ejecting unit 55 and the second evaporation-particle ejecting unit 56 are provided at the bottom inside the vacuum chamber 51.

The substrate supporting unit 52 includes: a substrate holder 52a that holds a target substrate 31; and a rotating mechanism 52b that rotates the substrate holder 52a. The rotating mechanism 52b includes, for example, a rotation shaft and a rotation drive unit such as a motor. The rotating mechanism 52b drives the rotation drive unit and rotates the drive shaft, in order to rotate the substrate holder 52a. When the substrate holder 52a rotates, the target substrate 31 held by the substrate holder 52a rotates.

Here, the target substrate 31 is used to form the second capping layer 16. The target substrate 31 has the lower electrode 12, the functional layer 13, the upper electrode 14, and the first capping layer 15, all of which are stacked on top of another above the substrate 11.

Each of the first evaporation-particle ejecting unit 55 and the second evaporation-particle ejecting unit 56 includes: a crucible that houses an evaporation material; and a heating system that heats the crucible.

The crucible is provided with an ejection port that ejects the evaporation material in the form of evaporation particles. In this embodiment, the crucible has an upper surface (i.e., a surface across from the shutter 53) provided with the ejection port. Each of the first evaporation-particle ejecting unit 55 and the second evaporation-particle ejecting unit 56 heats and vaporizes the evaporation material housed inside the crucible to generate the evaporation particles in a gaseous form. Note that the metal salt such as LiF and a Lewis base are, for example, solid, and the evaporation here specifically means, for example, sublimation. Note that this embodiment shall not be limited to such examples. For example, if the Lewis base is liquid, the evaporation may be vaporization.

The first evaporation-particle ejecting unit 55 ejects the vaporized evaporation material as evaporation particles 61 from the ejection port toward the target substrate 31. The second evaporation-particle ejecting unit 56 ejects the vaporized evaporation material as evaporation particles 62 from the ejection port toward the target substrate 31.

In this embodiment, as an example, the crucible of the first evaporation-particle ejecting unit 55 houses a metal salt, and the crucible of the second evaporation-particle ejecting unit 56 houses a Lewis base. Thus, the first evaporation-particle ejecting unit 55 is used as an evaporation source for evaporating the metal salt, and the second evaporation-particle ejecting unit 56 is used as an evaporation source for evaporating the Lewis base.

The vacuum chamber 51 has a vacuum of 10⁻⁵ Pa or less. A heating temperature of the Lewis base varies depending on a vacuum of the vacuum chamber 51, and on a kind and an evaporation rate of the Lewis base. The heating temperature is within a range of, for example, 50° C. or above and 300° C. or below. A heating temperature of the metal salt varies depending on a vacuum of the vacuum chamber 51, and on a kind and an evaporation rate of the metal salt. The heating temperature is within a range of, for example, 50° C. or above and 300° C. or below. Note that the metal salt such as LiF and the Lewis base are different in vaporization temperature (specifically sublimation temperature), and are thus different in heating temperature.

Between the first evaporation-particle ejecting unit 55 and the second evaporation-particle ejecting unit 56, a partition plate 57 is provided.

An evaporation rate of the metal salt is monitored with, for example, a first coating thickness gauge 58 provided toward the first evaporation-particle ejecting unit 55 near the shutter 53. Whereas, a film thickness rate of the Lewis base is monitored with a second coating thickness gauge 59 provided in a position that the metal salt does not enter.

The first coating thickness gauge 58 and the second coating thickness gauge 59 may be any given coating thickness gauges. The first coating thickness gauge 58 and the second coating thickness gauge 59 may be various known coating thickness gauges such as crystal monitors using crystal oscillators.

Theoretically, a composition ratio of the metal salt to the Lewis base (ligands) in a metal complex contained in the second capping layer 16 is 1:1 in terms of molar ratio. In order to set the molar ratio of the metal salt to the Lewis base contained in the second capping layer 16 to 1:1, a ratio of the deposition rate of the metal salt to the deposition rate of the Lewis base is adjusted to 1:1.

Note that, for the above reason, the second capping layer 16 does not desirably contain a metal salt that is not metal-complexed. Hence, in order to capture 100% of the metal salt to form a metal complex, the amount of the Lewis base to be used is desirably one or more times as much as the amount of the metal salt. Thus, in order to form the second capping layer 16, a proportion of the Lewis base with respect to 1 mol of the metal salt may be 1 mol or more. Preferably, the proportion may be 2 mol or more. In order to capture 100% of the metal salt to form a metal complex, a higher proportion of the Lewis base with respect to the metal salt produces a more desirable outcome. Note that an excessively large amount of the Lewis base might adversely affect the structure of the capping layer and the costs. Hence, the proportion of the Lewis base is preferably 3 mol or less.

Note that an evaporation rate of the metal salt and an evaporation rate of the Lewis base can be adjusted, for example, when the heating temperatures for the metal salt and the Lewis base are adjusted in accordance with results measured with the first coating thickness gauge and the second coating thickness gauge. In order to increase the proportion of the Lewis base with respect to the metal salt, for example, the heating temperature of the crucible of the second evaporation-particle ejecting unit 56 may be raised.

Note that the shutter 53 covers a portion included in the target substrate 31 and desirably kept from contact with the evaporation particles 61 and 62. The shutter 53 is supported by the shutter supporting unit 54. In accordance with an evaporation OFF signal and an evaporation ON signal from a not-shown control unit, the shutter 53 is activated, and the activated shutter 53 is appropriately inserted between the target substrate 31 and the crucible. Such a feature can prevent evaporation of a non-film-deposition region in the target substrate 31.

The metal salt and the Lewis base are evaporated so that the thickness of the second capping layer 16 (i.e., the total thickness of the mixed layer of the metal salt and the Lewis base) is equal to the above thickness. Hence, the second capping layer 16 is successfully formed.

Note that the produced complex can be identified by a known method such as nuclear magnetic resonance (NMR).

### Modification

Note that the method for forming the second capping layer 16 according to this embodiment shall not be limited to the above method.

FIG. 4 is a cross-sectional view schematically illustrating a configuration of another film depositing apparatus 70 to be used for forming the second capping layer 16.

The film depositing apparatus 70 includes: a vacuum chamber 71; a substrate supporting unit 72; a shutter 73; a not-shown shutter supporting unit; an evaporation-particle ejecting unit 74; and a coating thickness gauge 75.

The vacuum chamber 71, which is a film depositing chamber, is provided with a not-shown vacuum pump to exhaust air inside the vacuum chamber 71 through a not-shown exhaust port provided to the vacuum chamber 51, in order to maintain a vacuum inside the vacuum chamber 71.

In the vacuum chamber 71, the substrate supporting unit 72 is disposed across the shutter 73 from the evaporation-particle ejecting unit 74 serving as an evaporation source. In the example illustrated in FIG. 4, the substrate supporting unit 72 and the shutter 73 are provided at the top inside the vacuum chamber 71, and the evaporation-particle ejecting unit 74 is provided at the bottom inside the vacuum chamber 71.

The substrate supporting unit 72 includes: a substrate holder that holds the target substrate 31. The substrate supporting unit 72 may have the same configuration as the substrate supporting unit 52 has, and may either include or omit a rotating mechanism that rotates the substrate holder.

The evaporation-particle ejecting unit 74 includes: a crucible that houses an evaporation material; and a heating system that heats the crucible. The crucible is provided with an ejection port that ejects the evaporation material in the form of evaporation particles. In this embodiment, the crucible has an upper surface (i.e., a surface across from the shutter 73) provided with the ejection port.

The crucible houses a metal complex synthesized in advance. The metal complex may be a commercially available metal complex. In this modification, the metal complex housed in the crucible is heated and vaporized to form evaporation particles 81. The evaporation particles 81 are particles formed when the metal complex is vaporized. The evaporation-particle ejecting unit 74 ejects the vaporized evaporation material as the evaporation particles 81 from the ejection port toward the target substrate 31.

The vacuum chamber 71 has a vacuum of 10⁻⁵ Pa or less. A heating temperature of the metal complex varies depending on a vacuum of the vacuum chamber 71, and on a kind and an evaporation rate of the metal complex. The heating temperature is within a range of, for example, 50° C. or above and 300° C. or below.

An evaporation rate of the metal complex is monitored with the coating thickness gauge 75. The coating thickness gauge 75 may be included in various known coating thickness gauges such as crystal monitors using crystal oscillators.

Note that the shutter 73 covers a portion included in the target substrate 31 and desirably kept from contact with the evaporation particles 81. Also in this case, in accordance with an evaporation OFF signal and an evaporation ON signal from a not-shown control unit, the shutter 73 is activated, and the activated shutter 73 is appropriately inserted between the target substrate 31 and the crucible. Such a feature can prevent evaporation of a non-film-deposition region in the target substrate 31.

Note that FIG. 4 illustrates a case where a single evaporation-particle ejecting unit is used as the evaporation-particle ejecting unit. However, the evaporation-particle ejecting unit may include a plurality of (e.g., two to three) evaporation-particle ejecting units. Hence, for example, the film depositing apparatus 50 includes: the first evaporation-particle ejecting unit 55 having the crucible; and the second evaporation-particle ejecting unit 56 having the crucible, and each of the crucibles houses a metal complex. Thus, the second capping layer 16 may be formed, using the film depositing apparatus 50 illustrated in FIG. 3.

### Second Embodiment

Another embodiment of present disclosure will be described below. Note that, for convenience in description, like reference signs designate members having identical functions between this embodiment and the above embodiment. These members will not be elaborated upon repeatedly. This embodiment describes a difference from the first embodiment.

### Schematic Configuration of Light-Emitting Device

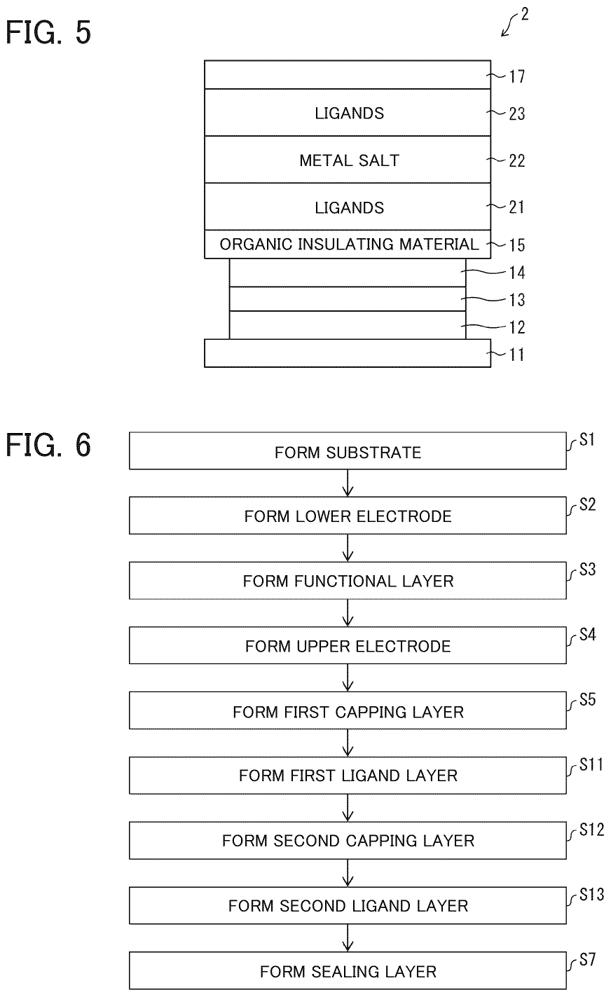

FIG. 5 is a cross-sectional view of an exemplary multilayer structure of the light-emitting device 2 according to this embodiment.

The light-emitting device 2 illustrated in FIG. 5 has the same configuration as the light-emitting device 1 has, except that, instead of the second capping layer 16, a first ligand layer 21, a second capping layer 22, and a second ligand layer 23 are stacked on top of another in the stated order above the first capping layer 15. That is, the light-emitting device 2 according to this embodiment includes, for example: the substrate 11; the lower electrode 12; the functional layer 13 including at least a light-emitting layer; the upper electrode 14; the first capping layer 15; the first ligand layer 21; the second capping layer 22; the second ligand layer 23; and the sealing layer 17, all of which are stacked on top of another in the stated order from toward the substrate 11.

Each of the first ligand layer 21, the second capping layer 22, and the second ligand layer 23 is provided so as to cover the entire surface of the light-emitting region. Similar to the second capping layer 16, each of the first ligand layer 21, the second capping layer 22, and the second ligand layer 23 functions as an optical adjustment layer that adjusts light emitted from the upper electrode 14 and also as a protective layer that protects the upper electrode 14. In this embodiment, the first capping layer 15, the first ligand layer 21, the second capping layer 22, and the second ligand layer 23 provided above the upper electrode 14 can prevent or keep water and oxygen from entering from above; that is, for example, from the sealing layer 17. Such a feature makes it possible to adjust optical characteristics such as viewing angle, lifetime, and light extraction efficiency.

The second capping layer 22 according to this embodiment contains a metal salt. The metal salt preferably contains at least one metal salt selected from an alkali metal salt and an alkali earth metal salt. Examples of the alkali metal salt and the alkali earth metal salt include the alkali metal salt and the alkali earth metal salt described in the first embodiment.

Furthermore, the at least one metal salt selected from the alkali metal salt and the alkali earth metal salt is preferably at least one halide selected from an alkali metal halide and an alkali earth metal halide. Examples of the alkali metal halide and the alkali earth metal halide include the alkali metal halide and the alkali earth metal halide described in the first embodiment.

Note that, also in this embodiment, the second capping layer 22 is desirably transparent to visible light, and lower in refractive index than the first capping layer 15, as seen in the second capping layer 16.

As can be seen, when each of the first capping layer 15 and the second capping layer 22 is formed of a light-transparent material, the light-emitting device 1 can include the first capping layer 15 and the second capping layer 22 each of which is transparent to light.

The first ligand layer 21 is provided adjacent to a lower surface of the second capping layer 22. The second ligand layer 23 is provided adjacent to an upper surface of the second capping layer 22.

Each of the first ligand layer 21 and the second ligand layer 23 contains ligands that form a complex together with either a metal element, or metal ions, contained in the metal salt.

The ligands contain a Lewis base. Also in this embodiment, the Lewis base shall not be limited to a particular Lewis base as long as the Lewis base has at least one unshared electron pair, and can donate electrons to the metal salt to form a metal complex. Note that, as described above, the first capping layer 15 and the second capping layer 22 are preferably transparent to visible light. Hence, the first ligand layer 21 and the second ligand layer 23 are also desirably transparent to visible light. Hence, also in this embodiment, the Lewis base is preferably a light-transparent Lewis base.

Furthermore, the Lewis base contains at least one atom selected from the group consisting of a nitrogen atom, an oxygen atom, and a phosphorus atom.

Hence, the ligands contained in the first ligand layer 21 and the second ligand layer 23 preferably contain a Lewis base containing at least one atom selected from the group consisting of a nitrogen atom, an oxygen atom, and a phosphorus atom. As described in the first embodiment, the nitrogen atom, the oxygen atom, and the phosphorus atom are negatively charged. Thanks to such a feature, positively charged metal ions are captured in greater amount so that the complex is readily formed. Simultaneously, the feature makes it possible to prevent deterioration of the optical characteristics more reliably.

Examples of the ligands include the Lewis base described in Embodiment 1. Specifically, examples of the ligands include a Lewis base containing at least one structural unit selected from the group consisting of structural units represented by Formulae (1) to (4) above.

Thus, also in this embodiment, the ligands (the Lewis base) may be monodentate ligands, or bidentate or higher multidentate ligands. Note that, as described above, compared with multidentate ligands, monodentate ligands have weaker binding strength with metal. Hence, the ligands contained in each of the first ligand layer 21 and the second ligand layer 23 preferably contain multidentate ligands.

Thus, also in this embodiment, each of n1, n2 and n3 in Formulae (1) to (3) is preferably independent and an integer of 2 or more. Furthermore, also in this embodiment, upper limit values of n1, n2, and n3 shall not be limited to particular values. However, because of the same reason described in the first embodiment, each of n1, n2, and n3 is preferably an integer of 9 or less. Furthermore, in Formula (4), each of n4 and n5 is preferably independent and an integer of 0 or 1 or more, and n4+n5 is an integer of 2 or more. For the same reason as for n1 to n3, each of n4 and n5 is preferably independent and an integer of 9 or less, and n4+n5 is preferably an integer of 9 or less.

Moreover, the ligands more preferably include tridentate or higher multidentate ligands having a cyclic structure. Hence, as to the ligands (a Lewis base) containing at least one structural unit represented by Formulae (1) to (3), each of n1, n2 and n3 is preferably independent and an integer of 3 or more and 9 or less, and the ligands preferably have a cyclic structure. Furthermore, as to the ligands (a Lewis base) containing a structural unit represented by Formula (4), each of n4 and n5 is preferably independent and an integer of 0 or 1 or more and 9 or less, and the ligands preferably have a cyclic structure.

Examples of cyclic multidentate ligands having such a cyclic structure include the cyclic multidentate ligands described in the first embodiment. Specifically, the examples include ligands (a Lewis base) represented by Formulae (8) to (13) above.

Note that, also in this embodiment, the ligands shall not be limited to cyclic ligands. The ligands may be chain ligands (a Lewis base) represented by Formulae (22), (23), (26) to (28), and (32) to (34).

If the above light-emitting device is the light-emitting device 2, a thickness of each of the layers in the light-emitting device 2 may be appropriately set in accordance with the material of each layer and the kind of a film depositing apparatus for depositing the layer, so that a desired optical path length can be obtained in accordance with a color of the light to be emitted. The thickness shall not be limited to a particular thickness. As to the light-emitting device 2, the thicknesses of the substrate 11, the lower electrode 12, the functional layer 13 including at least a light-emitting layer, the upper electrode 14, the first capping layer 15, the second capping layer 22, and the sealing layer 17 can be set in the same manner as in the known art. Hence, the thicknesses of the first capping layer 15 and the thickness of the second capping layer 22 shall not be limited to particular thicknesses, and may be appropriately set in accordance with optical properties of the light-emitting device 2 and the result of a reliability test.

Note that, as seen in the light-emitting device 1, if each layer is excessively thick, the light-emitting device 2 as a whole becomes thick. Accordingly, the light-emitting device 2 becomes large in size. Hence, also in this embodiment, the first capping layer 15 has a thickness within a range of preferably, for example, more than zero nanometer to several hundred nanometers. As an example, the first capping layer 15 has a thickness of more than 0 nm and 200 nm or less. Furthermore, because of the same reason, the second capping layer 22 has a thickness within a range of preferably, for example, more than zero nanometer to several hundred nanometers. As an example, the second capping layer 22 has a thickness of more than 0 nm and 100 nm or less.

Furthermore, upper limit values and lower limit values of the thicknesses of the first ligand layer 21 and the second ligand layer 23 shall not be limited to particular values, and may be appropriately set in accordance with optical properties of the light-emitting device 2 and the result of a reliability test. Note that, in order to sufficiently obtain the advantageous effects of the first ligand layer 21 and the second ligand layer 23, each of the first ligand layer 21 and the second ligand layer 23 preferably has a thickness of 1 nm or more. In addition, in order to reduce the risk that the light-emitting device 2 would increase in size, each of the first ligand layer 21 and the second ligand layer 23 has a thickness of reasonably, for example, several tens of nanometers or less.

### Advantageous Effects

Described next will be advantageous effects of the first ligand layer 21 and the second ligand layer 23.

As described in the first embodiment, if the second capping layer contains metal salts such as an alkali metal haloid salt and an alkali earth metal haloid salt, molecules of the metal salts are small and likely to diffuse into a layer adjacent to the second capping layer. Furthermore, if water enters from outside into such a second capping layer, metal ions such as alkali metal ions or alkali earth metal ions are generated. These metal ions might enter an adjacent layer. Moreover, the second capping layer made of such metal salts exhibits poor uniformity and airtightness, and readily allows water and oxygen to pass therethrough, which increasingly deteriorates optical properties and decreases reliability of the light-emitting device.

Whereas, in this embodiment, the ligand layers (i.e., the first ligand layer 21 and the second ligand layer 23) are provided adjacent to the lower surface and the upper surface of the second capping layer 22 containing the metal salts, and contain ligands that form a complex together with either a metal element, or metal ions, contained in the metal salt.

Hence, the metal salts or the metal ions, which have diffused from the second capping layer 22 into the first ligand layer 21 or the second ligand layer 23 adjacent to the second capping layer 22, react with the ligands contained in these ligand layers to form a stable metal complex. Note that the above metal complex is the same as the metal complex formed in the first embodiment.

As described in the first embodiment, metal complexes including alkali metal complexes such as an alkali metal haloid complex and alkali earth metal complexes such as an alkali earth metal haloid complex are larger than metal salts including an alkali metal haloid salt and an alkali earth metal haloid salt. Hence, the metal salts and the metal ions are trapped into the first ligand layer 21 and the second ligand layer 23.

Thus, this embodiment can provide the light-emitting device 2 that excels a known light-emitting device in optical properties including efficiency in releasing light. Furthermore, this embodiment makes it possible to reduce deterioration of the optical properties over time, and to provide the light-emitting device 2 with longer lifetime and higher reliability than those of a known light-emitting device.

### Method for Producing Light-Emitting Device 1

Described next will be a method for producing the light-emitting device 2 according to this embodiment.

FIG. 6 is a flowchart showing an exemplary method for producing the light-emitting device 2 according to this embodiment.

The method for producing the light-emitting device 2 according to this embodiment is the same as the method for producing the light-emitting device 1 according to the first embodiment until the first capping layer 15 is formed at Step S5. As shown in FIG. 6, in this embodiment, Step 5 is carried out as described above. After that, the first ligand layer 21 is formed (Step S11). Next, the second capping layer 22 is formed (Step S12). Next, the second ligand layer 23 is formed (Step S13). After that, the sealing layer 17 is formed (Step S7). Step S7 is the same as Step S7 according to the first embodiment. Hence, the method for producing the light-emitting device 2 according to this embodiment is the same as the method for producing the light-emitting device 1 according to the first embodiment except that Step S6 described above is replaced with Steps S11 to S13.

At each of Steps S11 to S13, a film depositing apparatus to be used is the same as the film depositing apparatus 50 illustrated in FIG. 3 or the film depositing apparatus 70 illustrated in FIG. 4, and different evaporation materials are housed in the crucibles of the respective film depositing apparatuses. Hence, the first ligand layer 21 and the second ligand layer 23 are formed. Specifically, the evaporation materials are evaporated in the order of the ligands (the Lewis base at Step S11), the metal salt (at Step S12), and the ligands (the Lewis base at Step S13).

Note that, also in this case, each of the vacuum chambers has a vacuum of 10⁻⁵ Pa or less. A heating temperature of the Lewis base varies depending on a vacuum of each vacuum chamber, and on a kind and an evaporation rate of the Lewis base. The heating temperature is within a range of, for example, 50° C. or above and 300° C. or below. Furthermore, a heating temperature of the metal salt also varies depending on a vacuum of a vacuum chamber of the film depositing apparatus, and on a kind and an evaporation rate of the metal salt. The heating temperature is within a range of, for example, 50° C. or above and 300° C. or below. Note that, as seen in the first embodiment, the metal salt such as LiF and the Lewis base are different in vaporization temperature (specifically sublimation temperature), and are thus different in heating temperature.

Note that if all of the metal salt contained in the second capping layer 22 is assumed to diffuse, the amount of the Lewis base to be used is desirably one or more times as much as the amount of the metal salt in order to capture 100% of the metal salt to form a metal complex. In this embodiment, a ligand layer is provided to each of the upper surface and the lower surface of the second capping layer 22. Thus, in order to cause all of the metal salt contained in the second capping layer 22 to form a complex, a total proportion of the Lewis bases, contained in the first ligand layer 21 and the second ligand layer 23, with respect to 1 mol of the metal salt contained in the second capping layer 22 may be in theory 1 mol or more. More preferably, the proportion is 2 mol or more. However, the metal salt does not always uniformly diffuse into the first ligand layer 21 and the second ligand layer 23. Thus, the proportion of each of the Lewis bases, contained in the first ligand layer 21 and the second ligand layer 23, with respect to 1 mol of the metal salt contained in the second capping layer 22 is preferably 1 mol or more. More preferably, the proportion is 2 mol or more. Note that, also in this embodiment, in order to capture 100% of the metal salt to form a metal complex, a higher proportion of the Lewis base with respect to the metal salt produces a more desirable outcome. Note that, an excessively large amount of the Lewis base might adversely affect the structure of the capping layer and the costs. Hence, the proportion of the Lewis base in each of the ligand layer is preferably 3 mol or less.

The metal salt and the Lewis base are evaporated so that each of the first ligand layer 21, the second capping layer 22, and the second ligand layer 23 has the thickness described above. As a result, the first ligand layer 21, the second capping layer 22, and the second ligand layer 23 are successfully formed.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. A light-emitting device, comprising:
a lower electrode; a functional layer including at least a light-emitting layer; an upper electrode; a first capping layer containing an organic insulating material; and a second capping layer containing a metal complex, all of which are stacked on top of another in a stated order.

2. The light-emitting device according to claim 1,
wherein the metal complex contains at least one complex selected from an alkali metal complex and an alkali earth metal complex.

3. The light-emitting device according to claim 2,
wherein the at least one complex selected from the alkali metal complex and the alkali earth metal complex is at least one halide complex selected from an alkali metal halide complex and an alkali earth metal halide complex.

4. The light-emitting device according to claim 1,
wherein ligands contained in the metal complex contain a Lewis base having at least one atom serving as a coordination atom and selected from the group consisting of a nitrogen atom, an oxygen atom, and a phosphorus atom.

5. The light-emitting device according to claim 1,
wherein ligands contained in the metal complex contain multidentate ligands.

6. The light-emitting device according to claim 1,
wherein ligands contained in the metal complex contain at least one structural unit selected from the group consisting of structural units represented by Formulae (1) to (4) below: 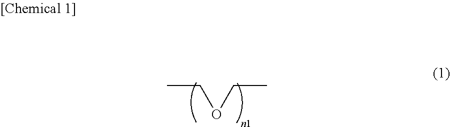
wherein n1 represents an integer of 1 or more; 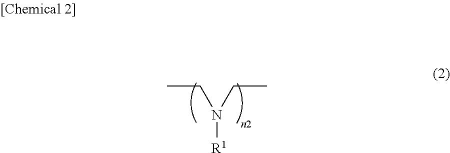
wherein R¹ represents either a hydrogen atom or a substituted or unsubstituted, and branched-chain, linear, or cyclic hydrocarbon group, and n2 represents an integer of 1 or more; 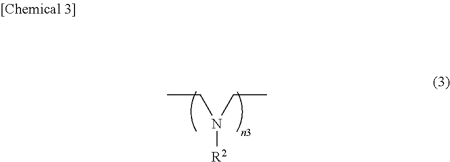
wherein R² represents either a hydrogen atom or a substituted or unsubstituted, and branched-chain, linear, or cyclic hydrocarbon group, and n3 represents an integer of 1 or more; and 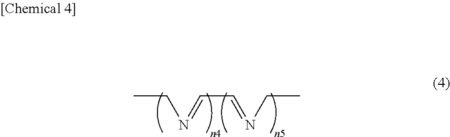
wherein each of n4 and n5 independently represents an integer of 0 or 1 or more, and n4+n5 represents an integer of 1 or more.

7. The light-emitting device according to claim 6,
wherein, each of the n1, the n2, and the n3 is independent and an integer of 2 or more and 9 or less, and
each of the n4 and the n5 is independent and an integer of 0 or 1 or more and 9 or less, and the n4+n5 is an integer of 2 or more and 9 or less.

8. The light-emitting device according to claim 6,
wherein, each of the n1, the n2, and the n3 is independent and an integer of 3 or more and 9 or less,
each of the n4 and the n5 is independent and an integer of 0 or 1 or more and 9 or less, and the n4+n5 is an integer of 3 or more and 9 or less, and
the ligands have a cyclic structure.

9. A light-emitting device, comprising:
a lower electrode; a functional layer including at least a light-emitting layer; an upper electrode; a first capping layer containing an organic insulating material; and a second capping layer containing a metal salt, all of which are stacked on top of another in a stated order; and
a ligand layer provided adjacent to a lower surface and an upper surface of the second capping layer, and containing ligands that form a complex together with either a metal element, or metal ions, contained in the metal salt.

10. The light-emitting device according to claim 9,
wherein the metal salt contains at least one metal salt selected from an alkali metal salt and an alkali earth metal salt.

11. The light-emitting device according to claim 10,
wherein the at least one metal salt selected from the alkali metal salt and the alkali earth metal salt is at least one halide selected from an alkali metal halide and an alkali earth metal halide.

12. The light-emitting device according to claim 9,
wherein the ligands contain a Lewis base containing at least one atom selected from the group consisting of a nitrogen atom, an oxygen atom, and a phosphorus atom.

13. The light-emitting device according to claim 9,
wherein the ligands contain multidentate ligands.

14. The light-emitting device according to claim 9,
wherein the ligands contain at least one structural unit selected from the group consisting of structural units represented by Formulae (1) to (4) below: 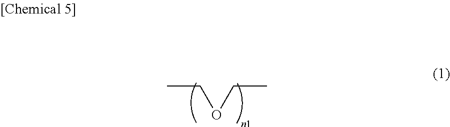
wherein n1 represents an integer of 1 or more; 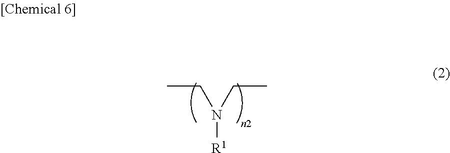
wherein R¹ represents either a hydrogen atom or a substituted or unsubstituted, and branched-chain, linear, or cyclic hydrocarbon group, and n2 represents an integer of 1 or more; 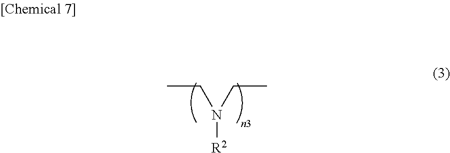
wherein R² represents either a hydrogen atom or a substituted or unsubstituted, and branched-chain, linear, or cyclic hydrocarbon group, and n3 represents an integer of 1 or more; and 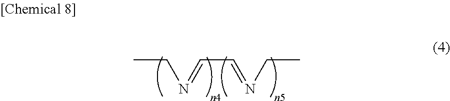
wherein each of n4 and n5 independently represents an integer of 0 or 1 or more, and n4+n5 represents an integer of 1 or more.

15. The light-emitting device according to claim 14,
wherein, each of the n1, the n2, and the n3 is independent and an integer of 2 or more and 9 or less, and
each of the n4 and the n5 is independent and an integer of 0 or 1 or more and 9 or less, and the n4+n5 is an integer of 2 or more and 9 or less.

16. The light-emitting device according to claim 14,
wherein, each of the n1, the n2, and the n3 is independent and an integer of 3 or more and 9 or less,
each of the n4 and the n5 is independent and an integer of 0 or 1 or more and 9 or less, and the n4+n5 is an integer of 3 or more and 9 or less, and
the ligands have a cyclic structure.

17. The light-emitting device according to claim 9,
wherein a proportion of the ligands, contained in the ligand layer, with respect to 1 mol of the metal salt contained in the second capping layer is 1 mol or more and 3 mol or less.

18. The light-emitting device according to claim 1,
wherein each of the first capping layer and the second capping layer is transparent to light.

19. The light-emitting device according to claim 1, further comprising
a sealing layer provided on the second capping layer.
